(19) United States
(12) Patent Application Publication
(10) Pub. No.: US 2024/0297271 A1
(43) Pub. Date: Sep. 5, 2024

(54) Light Emitting Diode Epitaxial Structure and Light Emitting Diode

(71) Applicant: HUAIAN AUCKSUN OPTOELECTRONICS TECHNOLOGY CO., LTD, Huaian (CN)

(72) Inventors: Tao Zhu, Huaian (CN); Changwei Song, Huaian (CN); Ling Lu, Huaian (CN)

(21) Appl. No.: 18/383,125

(22) Filed: Oct. 24, 2023

(30) Foreign Application Priority Data
Oct. 24, 2022 (CN) 202211302665.9

(51) Int. Cl. H01L 33/32; H01L 33/00; H01L 33/02; H01L 33/06

(52) U.S. Cl. CPC H01L 33/325; H01L 33/007; H01L 33/025; H01L 33/06

(57) ABSTRACT

A light emitting diode epitaxial structure and a light emitting diode are provided. The light emitting diode epitaxial structure includes a substrate, and an N-type semiconductor layer, an intermediate layer, a multi-quantum well layer and a P-type semiconductor layer which are sequentially arranged on the substrate, wherein the intermediate layer is doped with a n-type impurity, and a doping concentration of the n-type impurity is ≤4×10¹⁸ atoms/cm³. In a specific implementation of the present disclosure, the n-type impurity is Si, and the intermediate layer is a GaN layer doped with Si.

### CROSS-REFERENCE TO RELATED APPLICATION

The present disclosure claims the priority to the Chinese patent application with the filing No. 202211302665.9 filed with the Chinese Patent Office on Oct. 24, 2022, and entitled “Light Emitting Diode Epitaxial Structure and Light Emitting Diode”, the contents of which are incorporated herein by reference in entirety.

### TECHNICAL FIELD

The present disclosure relates to the technical field of semiconductor devices, in particular to a light emitting diode epitaxial structure and a light emitting diode.

### BACKGROUND ART

Light Emitting Diode (LED for short) is a kind of light emitting device, which can efficiently convert electric energy into light energy by combining electrons and holes, and is widely used in lighting, display and other fields. As a core part of LED, the epitaxial wafer has received a lot of attention and research. At present, the commonly used epitaxial wafer structure includes: substrate, N-type semiconductor layer, stress release layer, multi-quantum well layer and P-type semiconductor layer.

When used in a face-up structure LED chip, since the PN electrodes are on the same side of the LED, it is prone to be crowded. Poor expansion will lead to higher forward voltage of the chip, which further causes the chip to generate a larger amount of heat, and have short life and high energy consumption. Therefore, it is of great significance to solve the problems of high forward voltage and poor expansibility of the LED epitaxial wafer.

In view of this, the present disclosure is provided.

### SUMMARY

An objective of the present disclosure is to provide a light emitting diode epitaxial structure, so as to solve the technical problems of high forward voltage and poor expansibility of the LED epitaxial wafer in the prior art.

Another objective of the present disclosure is to provide a light emitting diode.

In order to achieve the above objectives of the present disclosure, the following technical solutions are adopted.

A light emitting diode epitaxial structure, including:
a substrate, and an N-type semiconductor layer, an intermediate layer, a multi-quantum well layer and a P-type semiconductor layer sequentially which are arranged on the substrate;
herein, the intermediate layer is doped with a n-type impurity, and an average doping concentration of the n-type impurity is ≤4×10¹⁸ atoms/cm³.

According to the light emitting diode epitaxial structure provided by the present disclosure, by arranging the optimized intermediate layer in front of the multi-quantum well layer, the current distribution is more uniform, the phenomenon of current congestion can be alleviated, improving the luminous efficiency.

In a specific implementation of the present disclosure, the n-type impurity is Si, and the intermediate layer is a GaN layer doped with Si.

In a specific implementation of the present disclosure, the intermediate layer includes:
a first expansion layer, located above the N-type semiconductor layer;
a second expansion layer, located above the first expansion layer; and
a third expansion layer, located between the second expansion layer and the multi-quantum well layer; and
average doping concentrations X, Y and Z of the n-type impurity in the first expansion layer, the second expansion layer and the third expansion layer satisfy: Y>Z>X.

In a specific implementation of the present disclosure, the average doping concentration of the n-type impurity in the first expansion layer is less than 3×10¹⁸ atoms/cm³, and/or a thickness of the first expansion layer is 100 to 300 nm.

In a specific implementation of the present disclosure, a maximum of the doping concentration of the n-type impurity in the second expansion layer is 2×10¹⁸ to 4×10¹⁸ atoms/cm³, and/or a thickness of the second expansion layer is 50 to 200 nm.

In a specific implementation of the present disclosure, the average doping concentration of the n-type impurity in the third expansion layer is less than 3×10¹⁸ atoms/cm³, and/or a thickness of the third expanding layer is 100 to 300 nm.

In a specific implementation of the present disclosure, the thicknesses H1, H2 and H3 of the first expansion layer, the second expansion layer and the third expansion layer satisfy: H1≥H3>H2.

In a specific implementation of the present disclosure, the second expansion layer includes at least one insertion layer, and an average doping concentration of the n-type impurity in the insertion layer is less than an average doping concentration of the n-type impurity in the second expansion layer.

In a specific implementation of the present disclosure, a direction from the first expansion layer to the third expansion layer is defined as a first direction, a doping concentration of the n-type impurity in the second expansion layer has a fluctuation along the first direction, the fluctuation of the concentration value of the n-type impurity includes at least one trough, and the trough corresponds to a concentration value of the n-type impurity in the insertion layer.

In a specific implementation of the present disclosure, the second expansion layer includes at least two expansion sublayers and an insertion layer arranged between two adjacent expansion sublayers, and the average doping concentration of the n-type impurity in the insertion layer is less than an average doping concentration of the n-type impurity in the expansion sublayers.

In a specific implementation of the present disclosure, the fluctuation of the concentration value of the n-type impurity includes at least one trough and at least two peaks, the trough corresponds to the concentration value of the n-type impurity in the insertion layer, and the peaks correspond to concentration values of the n-type impurity in the expansion sublayers.

In a specific implementation of the present disclosure, the concentration values corresponding to the peaks are 2×10¹⁸ to 4×10¹⁸ atoms/cm³, and the concentration value corresponding to the trough are 7×10¹⁷ to 1×10¹⁸ atoms/cm³.

In a specific implementation of the present disclosure, a thickness of the expansion sublayer near the first expansion layer is greater than or equal to a thickness of the expansion sublayer away from the first expansion layer.

In a specific implementation of the present disclosure, a thickness difference between the insertion layer and the expansion sublayer is less than or equal to 10 nm.

In a specific implementation of the present disclosure, the n-type impurity in the first expansion layer is uniformly doped, and the n-type impurity in the third expansion layer is uniformly doped.

In a specific implementation of the present disclosure, the third expansion layer is further doped with In. A concentration of In in the third expansion layer is less than a concentration of In in the multi-quantum well layer.

In a specific implementation of the present disclosure, the multi-quantum well layer includes at least one potential well/barrier pair sublayer, and a distance D1 between a center of the insertion layer and a center of the nearest potential well satisfies: 100 nm≤D1≤300 nm.

In a specific implementation of the present disclosure, the multi-quantum well layer includes a first multi-quantum well layer, a second multi-quantum well layer and a third multi-quantum well layer which are sequentially arranged from bottom to top;

the first multi-quantum well layer includes at least a first In-containing potential well/barrier pair sublayer; the second multi-quantum well layer includes at least a second In-containing potential well/barrier pair sublayer; the third multi-quantum well layer includes at least a third In-containing potential well/barrier pair sublayer; and

In content in the multi-quantum well layer satisfies: In content in the third In-containing potential well>In content in the second In-containing potential well>In content in the first In-containing potential well.

In a specific implementation of the present disclosure, a thickness of the multi-quantum well layer is 100 to 150 nm.

In a specific implementation of the present disclosure, a thickness of the potential well/barrier pair sublayer is 10 to 15 nm, and the potential well/barrier pair sublayer is InGaN/GaN.

In a specific implementation of the present disclosure, the P-type semiconductor layer is a P-type GaN layer doped with Mg, wherein an average doping concentration of Mg is 1×10¹⁹ to 1×10²¹ atoms/cm³.

In a specific implementation of the present disclosure, the light emitting diode epitaxial structure further includes a buffer layer arranged between the substrate and the N-type semiconductor layer.

In a specific implementation of the present disclosure, the N-type semiconductor layer includes an undoped GaN layer and an N-type GaN layer doped with Si, a thickness of the undoped GaN layer is 1.5 to 2.5 μm, and a thickness of the N-type GaN layer doped with Si is 1.5 to 2.5 μm.

In a specific implementation of the present disclosure, a doping concentration of Si in the N-type GaN layer doped with Si is 1×10¹⁹ to 1×10²⁰ atoms/cm³, such as 3×10¹⁹ atoms/cm³.

In a specific implementation of the present disclosure, the light emitting diode epitaxial structure further includes an electron blocking layer arranged between the multi-quantum well layer and the P-type semiconductor layer.

In a specific implementation of the present disclosure, the intermediate layer is further doped with a carbon impurity.

In a specific implementation of the present disclosure, a maximum doping concentration of the carbon impurity in the intermediate layer is less than or equal to 5×10¹⁷ atoms/cm³. Further, a maximum doping concentration of the carbon impurity in the intermediate layer is 3×10¹⁶ to 3×10¹⁷ atoms/cm³.

In a specific implementation of the present disclosure, average doping concentrations M, N and R of the carbon impurity in the first expansion layer, the second expansion layer and the third expansion layer satisfy: N≥R>M.

In a specific implementation of the present disclosure, the difference between the doping concentration of the carbon impurity in the first expansion layer and the concentration of the carbon impurity in the N-type semiconductor layer is less than or equal to 4×10¹⁶ atoms/cm³, and the doping concentration of the carbon impurity in the first expansion layer is greater than the concentration of the carbon impurity in the multi-quantum well layer.

In a specific implementation of the present disclosure, a maximum of the doping concentration of the carbon impurity in the second expansion layer and the third expansion layer is not higher than three times a maximum concentration of the carbon impurity in the N-type semiconductor layer.

In a specific implementation of the present disclosure, the maximum of the doping concentration of the carbon impurity in the second expansion layer and the third expansion layer is not higher than six times a maximum carbon impurity concentration in the multi-quantum well layer.

The present disclosure further provides a light emitting diode, which includes any one of the above light emitting diode epitaxial structures.

Compared with the prior art, the present disclosure has the following beneficial effects:
(1) According to the light emitting diode epitaxial structure provided by the present disclosure, by arranging the optimized intermediate layer in front of the multi-quantum well layer, the current distribution is more uniform, the phenomenon of current congestion can be alleviated, improving the luminous efficiency;
(2) According to the present disclosure, by adjusting the doping concentration of the n-type impurity, the crystal quality is prevented from decreasing due to too high impurity doping concentration, and meanwhile, the light efficiency is prevented from decreasing due to too low impurity doping concentration, increased resistance and increased working voltage. According to the present disclosure, the arrangement of the intermediate layer structure not only reduces the forward voltage of the light emitting diode, but also achieves effective expansion, improves the light efficiency and ensures the crystal quality;
(3) According to the present disclosure, by adjusting the content of the carbon impurity in the intermediate layer to achieve lower carbon doping concentration, defects are reduced, the growth quality is obviously improved, and meanwhile the electron transport performance is enhanced; in addition, low Si doping concentration and low-doped GaN thin layer further reduce defects and strengthen the effect of current expansion.

### BRIEF DESCRIPTION OF DRAWINGS

In order to more clearly illustrate the technical solutions in specific implementations of the present disclosure or in the prior art, a brief description of the accompanying drawings which needs to be used in the description of the specific implementations or the prior art will be introduced briefly below. Apparently, the accompanying drawings described below are merely some implementations of the present disclosure, and for those ordinarily skilled in the art, other drawings can be obtained in light of these drawings without creative effort.

FIG. 1 is a structural schematic diagram of a light emitting diode epitaxial structure provided by an embodiment of the present disclosure;

FIG. 2 is a structural schematic diagram of an intermediate layer provided by an embodiment of the present disclosure;

FIG. 3 is a structural schematic diagram of a multi-quantum well layer provided by an embodiment of the present disclosure;

FIG. 4 is a SIMS test result diagram of a light emitting diode epitaxial structure provided by an embodiment of the present disclosure;

FIG. 5 is a SIMS test result diagram of a light emitting diode epitaxial structure provided by another embodiment of the present disclosure;

FIG. 6 is a SIMS test result diagram of a light emitting diode epitaxial structure provided by yet another embodiment of the present disclosure; and

FIG. 7 is a structural schematic diagram of a light emitting diode provided by an embodiment of the present disclosure.

### REFERENCE NUMERALS

101—substrate; 102—buffer layer; 103—N-type semiconductor layer;
104—intermediate layer; 105—multi-quantum well layer; 106—electron blocking layer;
107—P-type semiconductor layer; 1041—first expansion layer; 1042—second expansion layer;
1043—third expansion layer; 1051—first multi-quantum well layer; 1052—second multi-quantum well layer;
1053—third multi-quantum well layer; 10421—insertion layer; 10422—expansion sublayer;
10511—first In-containing potential well/barrier pair sublayer; 10521—second In-containing potential well/barrier pair sublayer;
10531—third In-containing potential well/barrier pair sublayer.

### DETAILED DESCRIPTION OF EMBODIMENTS

The technical solutions of the present disclosure will be described clearly and completely with reference to the accompanying drawings and specific implementations, but those skilled in the art will understand that the embodiments described below are part rather than all of the embodiments of the present disclosure, and are only intended to illustrate the present disclosure and should not be regarded as limiting the scope of the present disclosure. Based on the embodiments in the present disclosure, all other embodiments obtained by a person skilled in the art without creative effort shall fall within the scope of protection of the present disclosure. Where specific conditions are not specified in the embodiments, it shall be implemented according to the conventional conditions or the conditions recommended by the manufacturer. The used reagents or instruments whose manufacturers are not indicated are conventional products that can be purchased in the market.

In the description of the present disclosure, it should be noted that the orientational or positional relationship indicated by the terms “center”, “upper”, “lower”, “left”, “right”, “vertical”, “horizontal”, “inner” and “outer”, etc. are based on the orientational or positional relationship shown in the accompanying drawings, which is only for the convenience of describing the present disclosure and simplifying the description, rather than indicating or implying that the referred apparatus or element must have a specific orientation and be constructed and operated in a specific orientation, and therefore should not be construed as limiting the present disclosure. In addition, the terms “first”, “second” and “third” are only intended for descriptive purposes and cannot be understood as indicating or implying relative importance.

When the existing LED epitaxial wafer is used in a face-up structure LED chip, since the PN electrodes are on the same side of the LED, it is prone to be crowded. Poor expansion will lead to higher forward voltage of the chip, which further causes the chip to generate a larger amount of heat, and have higher calorific value, short life and high energy consumption. In the embodiments of the present disclosure, by arranging the optimized intermediate layer in front of the multi-quantum well layer, the current distribution is more uniform, the phenomenon of current congestion can be alleviated, improving the luminous efficiency.

The embodiments of the present disclosure provide a light emitting diode epitaxial structure and a light emitting diode, which are described by embodiments below.

### Embodiment 1

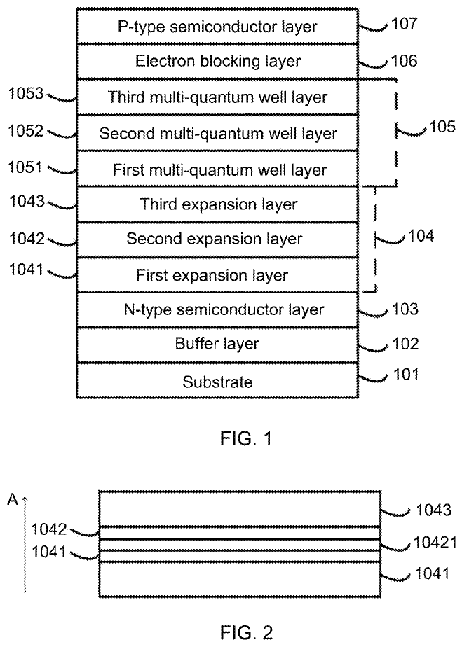

FIG. 1 is a schematic diagram of a light emitting diode epitaxial structure provided by an embodiment of the present disclosure. As shown in FIG. 1, the light emitting diode epitaxial structure includes:
a substrate 101, and a buffer layer 102, an N-type semiconductor layer 103, an intermediate layer 104, a multi-quantum well layer 105, an electron blocking layer 106 and a P-type semiconductor layer 107 which are sequentially and epitaxially grown on the substrate 101, wherein
the intermediate layer 104 is doped with a n-type impurity, and the average doping concentration of the n-type impurity is ≤4×10¹⁸ atoms/cm³.

In the embodiments of the present disclosure, as an optional embodiment, the n-type impurity is Si, and the intermediate layer 104 is a GaN layer doped with Si.

In the embodiments of the present disclosure, as an optional embodiment, the N-type semiconductor layer 103 is an N-type GaN layer, and the P-type semiconductor layer 107 is a P-type GaN layer.

In the embodiments of the present disclosure, as an optional embodiment, the intermediate layer 104 includes:
a first expansion layer 1041, located above the N-type semiconductor layer 103;
a second expansion layer 1042, located above the first expansion layer 1041;
a third expansion layer 1043, located between the second expansion layer 1042 and the multi-quantum well layer 105; and
the average doping concentrations X, Y and Z of the n-type impurity in the first expansion layer 1041, the second expansion layer 1042, and the third expansion layer 1043 satisfy: Y>Z>X.

In the embodiments of the present disclosure, as an optional embodiment, the average doping concentration of the n-type impurity in the first expansion layer 1041 is less than 3×10¹⁸ atoms/cm³; and/or the thickness of the first expansion layer 1041 is 100 to 300 nm. As another preferred optional embodiment, the average doping concentration of the n-type impurity in the first expansion layer 1041 is 5×10¹⁷ to 1×10¹⁸ atoms/cm³; and/or the thickness of the first expansion layer 1041 is 180 to 220 nm.

In the embodiments of the present disclosure, as an optional embodiment, the maximum of the doping concentration of the n-type impurity in the second expansion layer 1042 is 2×10¹⁸ to 4×10¹⁸ atoms/cm³; and/or the thickness of the second expansion layer 1042 is 50 to 200 nm. As another preferred optional embodiment, the maximum of the doping concentration of the n-type impurity in the second expansion layer is 1.5×10¹⁸ to 3.5×10¹⁸ atoms/cm³; and/or the thickness of the second expansion layer is 80 to 120 nm.

In the embodiments of the present disclosure, as an optional embodiment, the average doping concentration of the n-type impurity in the third expansion layer 1043 is less than 3×10¹⁸ atoms/cm³; and/or the thickness of the third expansion layer 1043 is 100 to 300 nm. As another preferred optional embodiment, the average doping concentration of the n-type impurity in the third expansion layer 1043 is 1.5×10¹⁸ to 2.5×10¹⁸ atoms/cm³, and/or the thickness of the third expansion layer 1043 is 130 to 170 nm.

By adjusting the doping concentration of the n-type impurity in the intermediate layer, the crystal quality is prevented from decreasing due to too high impurity doping concentration, and meanwhile, the light efficiency is prevented from decreasing due to too low impurity doping concentration, increased resistance and increased working voltage.

In the embodiments of the present disclosure, as an optional embodiment, the thicknesses H1, H2 and H3 of the first expansion layer 1041, the second expansion layer 1042 and the third expansion layer 1043 satisfy: H1≥H3>H2.

In the embodiments of the present disclosure, as an optional embodiment, referring to FIG. 2, the second expansion layer 1042 further includes at least one insertion layer 10421, and the average doping concentration of the n-type impurity in the insertion layer 10421 is less than the average doping concentration of the n-type impurity in the second expansion layer 1042.

In the embodiments of the present disclosure, as an optional embodiment, the direction from the first expansion layer 1041 to the third expansion layer 1043 is defined as the first direction A; the doping concentration of the n-type impurity in the second expansion layer 1042 has a fluctuation along the first direction A, and the fluctuation of the concentration value of the n-type impurity includes at least one trough; and the trough corresponds to the concentration value of the n-type impurity of the insertion layer 10421.

In the embodiments of the present disclosure, as an optional embodiment, the second expansion layer 1042 includes at least two expansion sublayers 10422 and an insertion layer 10421 arranged between two adjacent expansion sublayers 10422; and the average doping concentration of the n-type impurity in the insertion layer 10421 is less than the average doping concentration of the n-type impurity in the expansion sublayers 10422.

In the embodiments of the present disclosure, as an optional embodiment, the fluctuation of the concentration value of the n-type impurity at least includes one trough and two peaks; the trough corresponds to the concentration value of the n-type impurity in the insertion layer 10421, and the peaks correspond to the concentration values of the n-type impurity in the expansion sublayers 10422. Further, the fluctuation of the concentration values of the n-type impurity has several troughs and several peaks.

In the embodiments of the present disclosure, as an optional embodiment, the concentration values corresponding to the peaks are 2×10¹⁸ to 4×10¹⁸ atoms/cm³, and the concentration value corresponding to the trough are 7×10¹⁷ to 1×10¹⁸ atoms/cm³.

In the embodiments of the present disclosure, as an optional embodiment, the thickness of the expansion sublayer 10422 near the first expansion layer 1041 is greater than or equal to the thickness of the expansion sublayer 10422 away from the first expansion layer 1041.

In the embodiments of the present disclosure, as an optional embodiment, the thickness difference between the insertion layer 10421 and the expansion sublayer 10422 is ≤10 nm.

In the embodiments of the present disclosure, as an optional embodiment, the n-type impurity in the first expansion layer 1041 is uniformly doped, and the n-type impurity in the third expansion layer 1043 is uniformly doped. Herein, uniform doping refers to that the absolute value of the difference between the doping concentration of the n-type impurity and the average doping concentration in this layer is between 9×10¹⁶ and 3×10¹⁷ atoms/cm³, such as between 1×10¹⁷ and 2×10¹⁷ atoms/cm³.

In the embodiments of the present disclosure, as an optional embodiment, the third expansion layer 1043 is further doped with In. The concentration of In in the third expansion layer 1043 is less than the concentration of In in the multi-quantum well layer 105.

In the embodiments of the present disclosure, as an optional embodiment, the multi-quantum well layer 105 includes at least one potential well/barrier pair sublayer; the distance D1 between the center of the insertion layer 10421 and the center of the nearest potential well satisfies: 100 nm≤D1≤300 nm.

Herein, the potential well/barrier pair sublayer includes a potential well sublayer and a potential barrier sublayer, and the multi-quantum well layer 105 has a periodic structure in which the potential well sublayer and the potential barrier sublayer are alternately stacked. Further, the number of the periods may be 2 to 15.

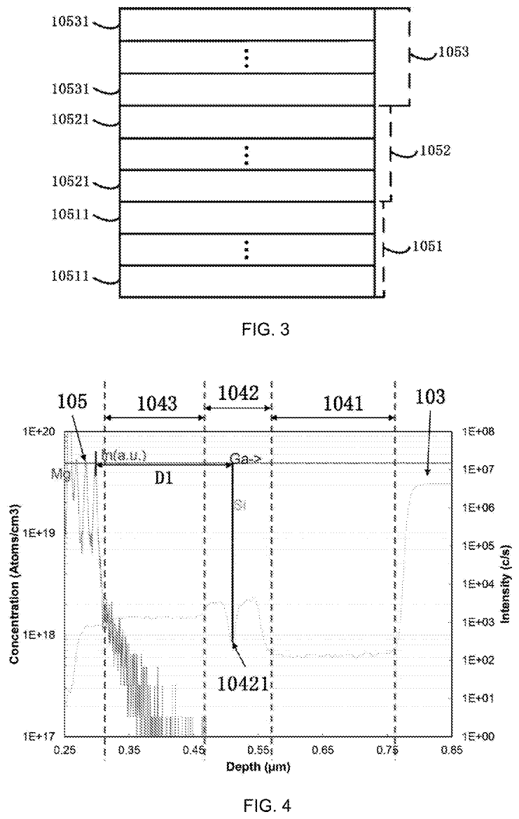

In the embodiments of the present disclosure, as an optional embodiment, referring to FIG. 3, the multi-quantum well layer 105 includes a first multi-quantum well layer 1051, a second multi-quantum well layer 1052 and a third multi-quantum well layer 1053 which are sequentially arranged from bottom to top.

The first multi-quantum well layer 1051 includes at least a first In-containing potential well/barrier pair sublayer 10511.

The second multi-quantum well layer 1052 includes at least a second In-containing potential well/barrier pair sublayer 10521.

The third multi-quantum well layer 1053 includes at least a third In-containing potential well/barrier pair sublayer 10531.

Herein, In content in the multi-quantum well layer 105 satisfies: In content in the third In-containing potential well>In content in the second In-containing potential well>In content in the first In-containing potential well.

FIG. 3 shows several corresponding In-containing potential well/barrier pair sublayers alternately stacked, wherein the number of layers of the corresponding In-containing potential well/barrier pair sublayers in the first multi-quantum well layer 1051, the second multi-quantum well layer 1052 and the third multi-quantum well layer 1053 can be adjusted according to actual needs.

Taking the first In-containing potential well/barrier pair sublayer 10511 as an example, the first In-containing potential well/barrier pair sublayer 10511 includes a first In-containing potential well sublayer and a first barrier sublayer; and the same is true for the second In-containing potential well/barrier pair sublayer 10521 and the third In-containing potential well/barrier pair sublayer 10531.

In the embodiments of the present disclosure, as an optional embodiment, the thickness of the multi-quantum well layer 105 is 100 to 150 nm.

In the embodiments of the present disclosure, as an optional embodiment, the thickness of the potential well/barrier pair sublayer is 10 to 15 nm; and the potential well/barrier pair sublayer is InGaN/GaN. Further, the thickness of the InGaN is 1 to 3 nm, and the thickness of the GaN is 9 to 12 nm.

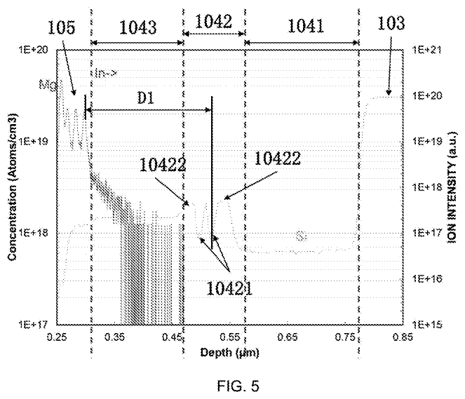

FIG. 4 is a SIMS test result diagram of a light emitting diode epitaxial structure provided by an optional embodiment of the present disclosure. As an optional embodiment, as shown in FIG. 4, the doping concentration of the n-type impurity in the second expansion layer 1042 has a fluctuation along the first direction A, the fluctuation of the concentration value of the n-type impurity includes a trough, and the trough corresponds to the concentration value of the n-type impurity in the insertion layer 10421.

### Embodiment 2

The difference between this embodiment and Embodiment 1 mainly lies in the structure of the intermediate layer. FIG. 5 is a SIMS test result diagram of a light emitting diode epitaxial structure provided by this embodiment. As shown in FIG. 5, the doping concentration of the n-type impurity in the second expansion layer 1042 has a fluctuation along the first direction A, the fluctuation of the concentration value of the n-type impurity includes two troughs and three peaks; the troughs correspond to the concentration values of the n-type impurity in the insertion layer 10421, and the peaks correspond to the concentration values of the n-type impurity in the expansion sublayers 10422.

In the embodiments of the present disclosure, as an optional embodiment, the P-type semiconductor layer 107 is a P-type GaN layer doped with Mg, wherein an average doping concentration of Mg is 1×10¹⁹ to 1×10²¹ atoms/cm³.

In the embodiments of the present disclosure, as an optional embodiment, the buffer layer 102 is one or more of AlN buffer layer, U-GaN buffer layer or AlGaN buffer layer, and the thickness of the buffer layer 102 is 15 to 25 nm.

In the embodiments of the present disclosure, as an optional embodiment, the N-type semiconductor layer 103 includes an undoped GaN layer and an N-type GaN layer doped with Si; a thickness of the undoped GaN layer is 1.5 to 2.5 μm; and a thickness of the N-type GaN layer doped with Si is 1.5 to 2.5 μm.

In the embodiments of the present disclosure, as an optional embodiment, the doping concentration of Si in the N-type GaN layer doped with Si is 1×10¹⁹ to 1×10²⁰ atoms/cm³, such as 3×10¹⁹ atoms/cm³.

In the embodiments of the present disclosure, as an optional embodiment, the electron blocking layer 106 is a P-type AlGaN electron blocking layer.

In the embodiments of the present disclosure, as an optional embodiment, the total thickness of the P-type AlGaN electron blocking layer and the P-type GaN layer doped with mg is 200 nm.

### Embodiment 3

The main difference between this embodiment and Embodiment 1 is that the intermediate layer not only includes impurity doped with Si, but also includes impurity doped with carbon.

In the embodiments of the present disclosure, as an optional embodiment, the intermediate layer 104 is doped with a carbon impurity, and the maximum doping concentration of the carbon impurity is ≤5×10¹⁷ atoms/cm³, preferably 3×10¹⁶ to 3×10¹⁷ atoms/cm³.

In the embodiments of the present disclosure, as an optional embodiment, the average doping concentrations M, N and R of the carbon impurity in the first expansion layer 1041, the second expansion layer 1042, and the third expansion layer 1043 satisfy: N≥R>M.

In the embodiments of the present disclosure, as an optional embodiment, the doping concentration of the carbon impurity in the first expansion layer 1041 is basically the same as the concentration of the carbon impurity in the N-type semiconductor layer 103, and the difference therebetween is ≤4×10¹⁶ atoms/cm³; and the doping concentration of the carbon impurity in the first expansion layer 1041 is greater than the concentration of the carbon impurity in the multi-quantum well layer 105.

In the embodiments of the present disclosure, as an optional embodiment, the maximum of the doping concentration of the carbon impurity in the second expansion layer 1042 and the third expansion layer 1043 is not higher than three times the maximum doping concentration of the carbon impurity in the N-type semiconductor layer 103.

In the embodiments of the present disclosure, as an optional embodiment, the maximum of the doping concentration of the carbon impurity in the second expansion layer 1042 and the third expansion layer 1043 is not higher than six times the maximum carbon impurity concentration of the multi-quantum well layer 105.

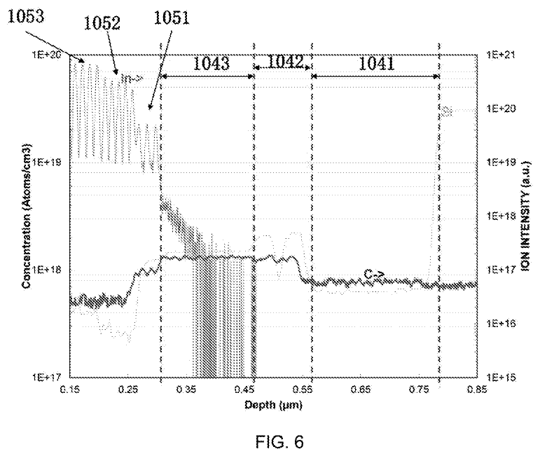

FIG. 6 is a SIMS test result diagram of a light emitting diode epitaxial structure provided by an optional embodiment of the present disclosure.

By controlling the growth conditions of the intermediate layer to modulate the content of the carbon impurity, a lower carbon doping concentration is formed, thus reducing defects, obviously improving the growth quality, and further enhancing the electron transport performance; Meanwhile, the combination of low Si doping concentration and low-doped thin layer further reduces defects, strengthens the effect of current expansion, and finally improves the light emitting efficiency of the light emitting diode.

An embodiment of the present disclosure further provides a method for preparing the light emitting diode epitaxial structure, which includes the following steps:
(1) growing an AlGaN buffer layer 102 with a thickness of 20 nm on the surface of the sapphire substrate 101 at 550° C.;
(2) performing annealing treatment in a NH₃ atmosphere, and raising the temperature to 1110° C., so as to recrystallize the low-temperature AlGaN into an island-like seed crystal;
(3) introducing TMGa (trimethylgallium) to grow a three-dimensional layer with a thickness of 1 μm under a pressure of 800 mbar;
(4) raising the temperature to 1150° C. and reducing the pressure to 600 mbar to grow an undoped GaN layer with a thickness of 2 μm;
(5) growing an N-type GaN layer doped with Si with a thickness of 2 μm under the same condition as in step (4), wherein the Si doping concentration is 3×10¹⁹ atoms/cm³;
(6) growing the intermediate layer 104, including:
   a first expansion layer 1041: cooling to 900° C., growing a GaN layer with a thickness of 100 to 300 nm at a pressure of 300 mbar, wherein a doping concentration of Si is lower than 3×10¹⁸ atoms/cm³; preferably, the thickness is 200 nm, and the Si doping concentration is 7×10¹⁷ atoms/cm³;
   a second expansion layer 1042: continuing to grow a GaN layer with a thickness of 50 to 200 nm, wherein a Si doping concentration is 2×10¹⁸ to 4×10¹⁸ atoms/cm³; preferably, the thickness is 100 nm and the Si doping concentration is 3×10¹⁸ atoms/cm³;
   in the middle of the second expansion layer 1042, growing an undoped GaN layer, namely the insertion layer 10421, with a thickness of 20 to 100 nm; the thickness is 10 to 100 nm; preferably, the thickness is 50 nm; and
   a third expansion layer 1043: under the same condition (the same condition as the first expansion layer 1041), growing a GaN layer with a thickness of 100 to 300 nm, wherein a doping concentration of Si is lower than 3×10¹⁸ atoms/cm³; preferably, the thickness is 150 nm, and the Si doping concentration is 2×10¹⁸ atoms/cm³;
(7) growing a multi-quantum well layer 105, which includes 10 pairs of InGaN (2 nm)/GaN (10 nm) light emitting layers with a total thickness of 120 nm, wherein the growth temperature of the GaN potential barrier layer is 870° C., the growth temperature of the InGaN potential well layer is 790° C., and gallium sources used in the InGaN potential well layer and the GaN potential barrier layer are both TEGa (triethylgallium);
(8) raising the temperature to 1000° C., and growing a P-type AlGaN electron blocking layer 106 under the pressure of 200 mbar; and
(9) turning off the aluminum source, keeping the same condition as in step (8), and continuing to grow the P-type GaN layer doped with Mg, that is, the P-type semiconductor layer 107, wherein the doping concentration of Mg in the P-type GaN layer doped with Mg is 1×10²⁰ atoms/cm³.

The total thickness of the P-type AlGaN electron blocking layer 106 and the P-type semiconductor layer 107 is 200 nm.

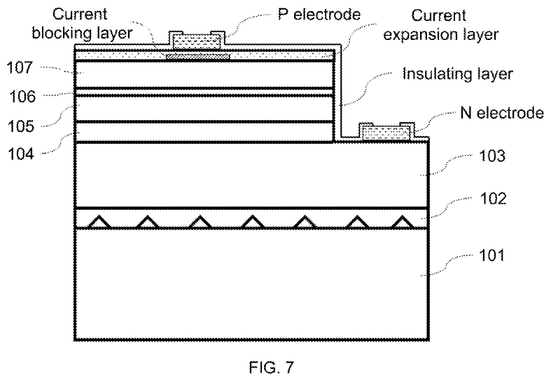

The present disclosure further provides a light emitting diode, as shown in FIG. 7, which includes any one of the above light emitting diode epitaxial structures.

Further, the light emitting diode further includes a light emitting diode epitaxial structure current blocking layer, a current expansion layer, an N electrode, a P electrode and an insulating layer.

The current blocking layer is arranged on the P-type semiconductor layer 107 of the light emitting diode epitaxial structure; the current expansion layer is stacked on the P-type semiconductor layer 107 in a manner of wrapping the current blocking layer; the p electrode is arranged on the current expansion layer and electrically connected to the P-type semiconductor layer 107; the N electrode is arranged in the N step region and is electrically connected to the N-type semiconductor layer 103; and the insulating layer covers the P electrode and the N electrode, and exposes part of the P electrode and the N electrode to form an opening.

Finally, it should be noted that the above embodiments are only intended to illustrate but not to limit the technical solutions of the present disclosure. Although the present disclosure has been described in detail with reference to the aforementioned embodiments, it should be understood by those ordinarily skilled in the art that the technical solutions described in the aforementioned embodiments may still be modified, or some or all of their technical features may be substituted by equivalents. However, these modifications or substitutions do not make the essence of the corresponding technical solutions deviate from the scope of the technical solutions of various embodiments of the present disclosure.

What is claimed is:

1. A light emitting diode epitaxial structure, comprising:
a substrate, and an N-type semiconductor layer, an intermediate layer, a multi-quantum well layer and a P-type semiconductor layer which are sequentially arranged on the substrate,
wherein the intermediate layer is doped with a n-type impurity, and an average doping concentration of the n-type impurity is less than or equal to 4×10¹⁸ atoms/cm³;
the intermediate layer comprises:
a first expansion layer, located above the N-type semiconductor layer;
a second expansion layer, located above the first expansion layer; and
a third expansion layer, located between the second expansion layer and the multi-quantum well layer; and
the second expansion layer comprises at least one insertion layer, and an average doping concentration of the n-type impurity in the insertion layer is less than an average doping concentration of the n-type impurity in the second expansion layer.

2. The light emitting diode epitaxial structure according to claim 1, wherein the n-type impurity is Si, and the intermediate layer is a GaN layer doped with Si;
and/or
average doping concentrations X, Y and Z of the n-type impurity in the first expansion layer, the second expansion layer and the third expansion layer satisfy: Y>Z>X.

3. The light emitting diode epitaxial structure according to claim 2, wherein the average doping concentration of the n-type impurity in the first expansion layer is less than 3×10¹⁸ atoms/cm³; and/or a thickness of the first expansion layer is 100 to 300 nm;
and/or
a maximum of the doping concentration of the n-type impurity in the second expansion layer is 2×10¹⁸ to 4×10¹⁸ atoms/cm³; and/or a thickness of the second expansion layer is 50 to 200 nm;
and/or
the average doping concentration of the n-type impurity in the third expansion layer is less than 3×10¹⁸ atoms/cm³; and/or a thickness of the third expanding layer is 100 to 300 nm;
and/or
the n-type impurity in the first expansion layer is uniformly doped, and the n-type impurity in the third expansion layer is uniformly doped;
and/or
the thicknesses H1, H2 and H3 of the first expansion layer, the second expansion layer and the third expansion layer satisfy: H1≥H3>H2.

4. The light emitting diode epitaxial structure according to claim 2, wherein a direction from the first expansion layer to the third expansion layer is defined as a first direction, a doping concentration of the n-type impurity in the second expansion layer has a fluctuation along the first direction, the fluctuation of the concentration value of the n-type impurity comprises at least one trough, and the trough corresponds to a concentration value of the n-type impurity in the insertion layer.

5. The light emitting diode epitaxial structure according to claim 4, wherein the second expansion layer comprises at least two expansion sublayers and an insertion layer arranged between two adjacent expansion sublayers, wherein the average doping concentration of the n-type impurity in the insertion layer is less than an average doping concentration of the n-type impurity in the expansion sublayers.

6. The light emitting diode epitaxial structure according to claim 5, wherein the fluctuation of the concentration value of the n-type impurity comprises at least one trough and at least two peaks, wherein the trough corresponds to the concentration value of the n-type impurity in the insertion layer, and the peaks correspond to concentration values of the n-type impurity in the expansion sublayers.

7. The light emitting diode epitaxial structure according to claim 6, wherein the concentration values corresponding to the peaks are 2×10¹⁸ to 4×10¹⁸ atoms/cm³, and the concentration value corresponding to the trough is 7×10¹⁷ to 1×10¹⁸ atoms/cm³.

8. The light emitting diode epitaxial structure according to claim 5, wherein a thickness of the expansion sublayer near the first expansion layer is greater than or equal to a thickness of the expansion sublayer away from the first expansion layer;
and/or
a thickness difference between the insertion layer and the expansion sublayer is less than or equal to 10 nm.

9. The light emitting diode epitaxial structure according to claim 4, wherein the third expansion layer is further doped with In.

10. The light emitting diode epitaxial structure according to claim 9, wherein a concentration of In in the third expansion layer is less than a concentration of In in the multi-quantum well layer.

11. The light emitting diode epitaxial structure according to claim 9, wherein the multi-quantum well layer comprises at least one potential well/barrier pair sublayer, and a distance D1 between a center of the insertion layer and a center of the nearest potential well satisfies: 100 nm≤D1≤300 nm.

12. The light emitting diode epitaxial structure according to claim 11, wherein a thickness of the potential well/barrier pair sublayer is 10 to 15 nm.

13. The light emitting diode epitaxial structure according to claim 1, wherein the multi-quantum well layer comprises a first multi-quantum well layer, a second multi-quantum well layer and a third multi-quantum well layer which are sequentially arranged from bottom to top;
the first multi-quantum well layer comprises at least a first In-containing potential well/barrier pair sublayer;
the second multi-quantum well layer comprises at least a second In-containing potential well/barrier pair sublayer;
the third multi-quantum well layer comprises at least a third In-containing potential well/barrier pair sublayer,
wherein In content in the multi-quantum well layer satisfies: In content in the third In-containing potential well>In content in the second In-containing potential well>In content in the first In-containing potential well.

14. The light emitting diode epitaxial structure according to claim 1, wherein the P-type semiconductor layer is a P-type GaN layer doped with Mg, wherein an average doping concentration of Mg is 1×10¹⁹ to 1×10²¹ atoms/cm³;
and/or
the light emitting diode epitaxial structure further comprises a buffer layer arranged between the substrate and the N-type semiconductor layer;
and/or
the N-type semiconductor layer comprises an undoped GaN layer and an N-type GaN layer doped with Si, wherein a thickness of the undoped GaN layer is 1.5 to 2.5 μm, and a thickness of the N-type GaN layer doped with Si is 1.5 to 2.5 μm.

15. The light emitting diode epitaxial structure according to claim 14, wherein a doping concentration of Si in the N-type GaN layer doped with Si is 1×10¹⁹ to 1×10²⁰ atoms/cm³, and/or
the light emitting diode epitaxial structure further comprises an electron blocking layer arranged between the multi-quantum well layer and the P-type semiconductor layer.

16. The light emitting diode epitaxial structure according to claim 2, wherein the intermediate layer is doped with a carbon impurity.

17. The light emitting diode epitaxial structure according to claim 16, wherein a maximum doping concentration of the carbon impurity in the intermediate layer is ≤5×10¹⁷ atoms/cm³.

18. The light emitting diode epitaxial structure according to claim 16, wherein a maximum doping concentration of the carbon impurity in the intermediate layer is 3×10¹⁶ to 3×10¹⁷ atoms/cm³.

19. The light emitting diode epitaxial structure according to claim 16, wherein average doping concentrations M, N and R of the carbon impurity in the first expansion layer, the second expansion layer and the third expansion layer satisfy: N≥R>M; and/or
a difference between a doping concentration of the carbon impurity in the first expansion layer and a concentration of the carbon impurity in the N-type semiconductor layer is less than or equal to 4×10¹⁶ atoms/cm³,
and the doping concentration of the carbon impurity in the first expansion layer is greater than a concentration of the carbon impurity in the multi-quantum well layer; and/or
a maximum of the doping concentration of the carbon impurity in the second expansion layer and the third expansion layer is not higher than three times a maximum concentration of the carbon impurity in the N-type semiconductor layer; and/or
the maximum of the doping concentration of the carbon impurity in the second expansion layer and the third expansion layer is not higher than six times a maximum carbon impurity concentration in the multi-quantum well layer.

20. A light emitting diode, comprising the light emitting diode epitaxial structure according to claim 1.
